(19) United States
(12) Patent Application Publication
(10) Pub. No.: US 2008/0251020 A1
(43) Pub. Date: Oct. 16, 2008

(54) Cvd-Reactor with Slidingly Mounted Susceptor Holder

(76) Inventors: Walter Franken, Eschweiler (DE); Johannes Kappeler, Wurselen (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 12/093,940

(22) PCT Filed: Nov. 17, 2006
(86) PCT No.: PCT/EP06/68621

§ 371 Date: May 15, 2008

(30) Foreign Application Priority Data
Nov. 19, 2005 (DE) 10 2005 055 252.8

(51) Int. Cl. C23C 16/00

(52) U.S. Cl. 118/730

(57) ABSTRACT

The invention relates to a device for depositing at least one layer on a substrate having one or more susceptors (7) for receiving substrates, comprising a substrate holder (6) that can be rotatably driven and forms the bottom of a process chamber (2), a RF heating system (22) disposed below the susceptor holder (6) and a gas inlet element (4) for introducing process gases into the process chamber. In order to further develop the generic device and to improve the production and advantages of use, it is proposed that the susceptor holder (6) lies in a sliding manner on an essentially IR- and/or RF-permeable supporting plate (14).

The invention relates to apparatus for deposition of at least one layer on a substrate, the apparatus comprising one or more susceptors for receiving substrates, a susceptor holder which can be driven in rotation, the susceptor holder defining the floor of a process chamber, a heater disposed underneath the susceptor holder and a gas inlet feature for the introduction of process gases into the process chamber.

An apparatus of this kind is known from DE 100 43 600 A1. A CVD reactor is therein described which has a process chamber in its reaction chamber, the floor of the process chamber being formed by a susceptor holder, the susceptor holder having, in a plurality of pockets, in each case susceptors driven in rotation by a gas bearing. A substrate lies on each of these circular disk-shaped susceptors, the substrate being coated in the process chamber. The susceptors and the susceptor holder are heated from below by means of RF. For this, a HF coil is located in the reactor chamber, outside the process chamber. By virtue of the eddy currents induced in the susceptors and in the susceptor holder, the heat needed to achieve the process temperature is developed. The process gases are introduced into the process chamber by way of a gas inlet feature, which is located in the center of the process chamber, so that the process gases can move outwards in the radial direction, where they are collected by a gas collector. In order to supply the rotary gas bearing with the gas needed to generate the gas bearing and the rotational impetus, the susceptor holder has not only vertical passages but also horizontal passages, since the gas supply for the rotary gas bearing is effected from the center.

US 2003/0188687 A1 describes a similar substrate holder. Here also, a susceptor holder is to be mounted rotatably. The holder is seated in a bearing recess in the floor of the process chamber. The holder hovers on a gas bearing and is in this way also floatingly mounted. The entire apparatus, and in particular the plate for receiving the susceptor holder, is however made from graphite, thus straightaway not transparent to IF and RF.

US 2005/0051101 A1 describes a reactor consisting of an upper part and a lower part. The two reactor parts form between them a chamber in which a substrate is to be located, the substrate to be rotatably supported by gas introduced through suitably formed nozzles. U.S. Pat. No. 6,824,619 B1 describes a similar apparatus.

U.S. Pat. No. 6,005,226 describes a rapid thermal imaging apparatus, in which the substrate is to be supported either on a gas bearing or on individual needle tips. A susceptor for receiving a substrate is not provided here in the strict sense. The elements carrying the substrate are formed from quartz.

U.S. Pat. No. 5,226,383 describes an RF-heatable reactor, in which a susceptor consisting of graphite is located in a receiver cavity of a susceptor holder consisting of graphite.

EP 0 519 608 A1 describes a heatable, non-transparent susceptor block, which defines a cavity in which a highly conductive susceptor is located.

WO 2005/121417 A1 describes a susceptor which is located in a cavity in a susceptor holder. Both parts are to consist of graphite.

It is an object of the invention to develop the apparatus of the generic kind in respect of production technology and to be advantageous in use.

The object is met by the invention specified in the claims. Each of the claims represents fundamentally an independent solution to the problem and may be combined with any other claim.

Claim 1 provides first and foremost that the susceptor holder is supported on a gas bearing. For this, a support plate is provided which is associated with the reactor in a non-rotatable manner. The support plate lies in the horizontal, as does the susceptor holder, so that a horizontal floating plane is defined. Heat transfer between the support plate and the susceptor holder is not necessary, since the support plate consists of material which is substantially transparent to IR and/or RF. As a result of this transparency with respect to the high frequency radiation or the infrared light used for the heating, the support plate does not heat up to any substantial extent. The energy from the light or the high frequency field gets right into the susceptor holder, which heats up in known manner. In a further development of the invention, it is provided that the susceptor floats on a gas bearing. For this, supply openings may be provided in the support plate, through which the gas forming the floating gas bearing may enter into the intermediate space between the support plate and the susceptor holder. The susceptor holder rises up slightly relative to the support plate. While the support plate does not rotate relative to the reactor, the susceptor holder can rotate. It is, for example, carried along by a rotary drive column. It may be displaced slightly in the axial direction relative to the rotary drive column, so that the gas gap between the support plate and the susceptor holder may be adjusted. In a preferred embodiment of the invention, the susceptors may be located in pockets on rotary gas bearings. For this, gas outlet nozzles are associated with the base of the pockets, by means of which a rotary gas bearing may be established in known manner underneath the susceptors. The gas entering through the nozzles comes from an annular channel, which extends between the susceptor holder and the support plate. This annular channel is fed with a gas by way of a passage through the support plate. The support plate may be supported on spherically-shaped flanges in the region of the passages through the support plate, the flanges being associated with gas supply lines. The gas supply lines are quartz tubes and may project through the windings of the RF coil or a heater winding. The gas inlet feature is located in the center of the process chamber. Different process gases may be introduced into the process chamber through the gas inlet feature at different levels above the susceptor holder. The process gases flow through the process chamber from inward to outward in the radial direction. Towards the top, the process chamber is bounded by a process chamber cover. In a preferred embodiment, the pockets are formed by one or more cover plates.

Association of the susceptor holder with a support plate enables supply of a gas to different points on the susceptor holder, in particular to form a rotary gas bearing for susceptors, without the susceptor holder requiring to have channels running in its plane of rotation. Accordingly, the problem is also solved by the susceptor holder being supported in a floating manner on a support plate, an annular channel being formed in the separation plane between the susceptor holder and the support plate, the annular channel being concentric with the axis of rotation of the susceptor holder, and gas entry openings associated with the support plate, through which openings the gas is introduced into the annular channel, opening out into the annular channel, and gas exit openings associated with the susceptor holder, through which the gas can exit out of the nozzles disposed on the process chamber side of the susceptor holder, also joining the annular channel. If this gas is not used for rotary drive of susceptors, but is used otherwise, for example as process gas, the susceptors may alternatively be integrally connected to the susceptor holder. The susceptors thus form zones of the susceptor holder.

An exemplary embodiment of the invention is explained on the basis of the accompanying drawings, in which:

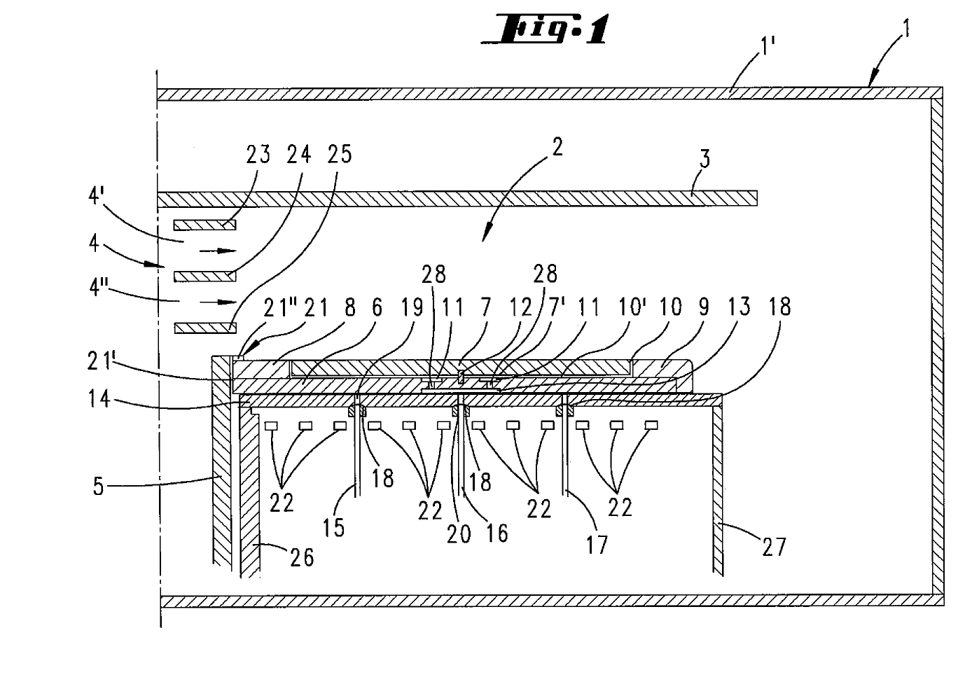

FIG. 1 shows a cross-section through a reactor chamber which is configured to be substantially rotationally symmetrical, and

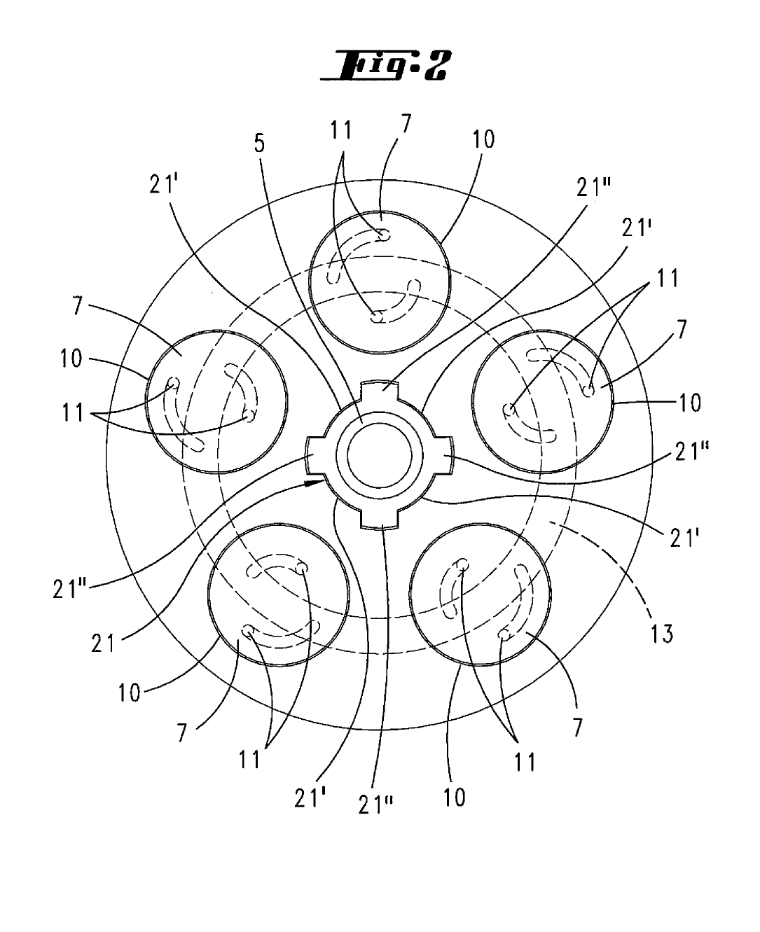

FIG. 2 shows the view onto the susceptor holder with the susceptors located therein in pockets and the head of a rotary drive column.

The exemplary embodiment is an MOCVD reactor 1. Only the components of the reactor 1 which are of significance for the explanation of the invention are shown in the drawings. The reactor chamber of the reactor 1 is enclosed in a gastight manner by a reactor wall 1′. Within the reactor 1, there is located a process chamber 2, in which the CVD-process takes place. The process chamber 2, which extends in the horizontal direction, is bounded at the top by a process chamber cover 3. The lower boundary of the process chamber 2 is effected by the susceptor holder 6, with the cover plates 8, 9 and susceptors 7 supported thereon.

In regard to the details of the construction of a reactor of this kind, reference is made to DE 100 43 600 A1, mentioned at the beginning, the full content of which is incorporated into this application.

The process gases are introduced into the center of the process chamber 2 by means of a gas inlet feature 4. Guide plates designated by the reference numerals 23, 24, 25 are located there and form, between them, the horizontal, rotationally symmetrical gas inlet channels 4′, 4″. The supply of the gases may be effected from below or from above. For this, a gas inlet feature may be used as is in principle already known from the state of the art.

A rotary drive column is designated by the reference numeral 5. This rotary drive column 5 is set in rotation by way of a rotary drive means, not illustrated. This non-illustrated rotary drive means may be located within the reactor chamber or alternatively outside the reactor chamber. What is significant is that the rotary drive column is rotationally coupled to the susceptor holder 6. The susceptor holder 6 consists substantially of a circular graphite plate with a central aperture. This central aperture has recesses arranged in the manner of a cross. Drive features 21″ of the rotary drive column 5 engage in these recesses. Drive features 21′ of the susceptor holder 6 are located between these drive features 21″.

The underside of the susceptor holder 6 lies on a support plate 14. The support plate 14 consists of a material which is transparent to a high frequency, for example quartz.

A HF-heater in the form of a flat coil 22 is located underneath the support plate 14. A heating coil may alternatively be provided instead of the HF-coil. Gas supply lines 15, 16, 17 formed by quartz tubes project in the vertical direction through the windings of the flat coil 22. The heads of these gas supply lines 15, 16, 17 are in each case formed by a spherically-shaped flange 18. The support plate 14 has receiving hollows corresponding to the spherically-shaped flanges 18, the support plate 14 being supported on the spherically-shaped flanges 18 by these hollows. Gas passages 19, 20 are located in the centers of these hollows, the passages opening out into the intermediate gap space between the support plate 14 and the susceptor holder 6. The middle gas supply line 16 opens out into an annular channel 13, which is formed by a groove on the lower side of the susceptor holder 6. Gas supply lines 28 extend from this annular channel 13 and open out into drive nozzles 11, which are disposed on the base 10′ of a pocket 10. A centering pin 12 is located in the center of the pocket 10 which has a circular cross-section, about which pin a susceptor 7 is rotatably mounted. The centering pin 12 is not essential, but is merely advantageous.

In operation, the susceptor 7, which is in the shape of a circular disk and likewise consists of graphite, is supported on a rotary gas bearing. The rotary gas bearing is generated by the gas which exits through the drive nozzles 11. The annular channel 13 which supplies the drive nozzles 11 with gas is fed through the gas supply line 16, which is located underneath the annular channel 13. A plurality of gas supply lines 16 of this kind may be provided, distributed over the entire circumference.

A carrier gas, for example hydrogen, is introduced, through the gas supply line 15 near the center of the process chamber 2 and through the gas supply line 17 near the edge of the process chamber 2, into the gap between the susceptor holder 6 and the support plate 14, this lifting the susceptor holder slightly relative to the support plate 14. In this way, a gas bearing is formed.

The above-mentioned pockets 10 are formed in the exemplary embodiment by cover plates 8, 9, which are supported in a planar manner on the upper side of the susceptor holder 6. The thickness of the cover plates 8, 9 is selected so that in the, raised condition, the upper surface of the susceptor 7 is aligned with the upper surface of the cover plates 8, 9. The radially outward cover plate 9 has an angled portion which engages over the edge of the susceptor holder 6.

The cover plates 8, 9 are preferably of a coated graphite.

As a result of the configuration according to the invention, it is possible to supply the pockets 10 with a gas without a horizontal channel within the susceptor holder 6, the gas forming a gas bearing for the susceptor 7 located in the pocket. The susceptor holder lacks homogeneity only in the region of the annular channel 13.

The support plate 14 may be supported on support bodies 26, 27 of tubular form, these being fixedly connected to the housing. A first support body 26 of tubular form, which surrounds the rotary drive column 5 at a small spacing, supports that edge of the support plate 14 which is directed towards the central opening. A support tube 27 of greater diameter is mounted in the outer edge of the support plate 14.

The coating process carried out in the process chamber 2 is an MOCVD process. For this, the process gases are introduced through the channels 4′, 4″ of the gas inlet feature. The channels 41, 4″ are formed by guide plates 23, 24, 25 which extend horizontally and are located one over the other at a spacing. The outlet openings of the channels 4′, 4″ extend as a result along a cylindrical outer surface. Arsene, phosphine or ammonia can exit from the lower outlet opening, this being associated with the channel 4′. These process gases may be diluted with hydrogen or nitrogen as a carrier gas. A metal-organic compound, for example an aluminum, gallium or indium compound, is introduced into the process chamber 2 from the upper channel 4″. By virtue of a surface reaction on the substrate, which is not illustrated but is supported on the susceptor 7, the crystal-forming elements of the fifth and third main group are released, in order to there grow as gallium arsenide or gallium nitrite or a crystal mixture. The products of the reaction and unwanted reaction components and the carrier gas are conducted away via peripheral gas collection features, not illustrated. The removal of the gas may be effected by way of a vacuum pump, which is likewise not illustrated. The supply of the process gases and also of the carrier gases, which are introduced into the process chamber 2 in the center of the process chamber, is effected in the radial direction through a suitable conduit system.

As is to be gathered from FIG. 2, the nozzles 11 open out into, in particular, arcuate grooves which extend in a spiral shape, in order in this way to exert a rotational moment on the susceptors.

By suitable dimensioning of the gas supply line 16, it is possible to dispense with the further gas supply lines 15, 17. It is only necessary for one gas to be introduced into the annular channel 13. The openings of the drive nozzles 11 form a flow resistance, so that when the annular channel 16 is suitably dimensioned, a part of the gas introduced through the gas supply line 16 does not flow through the drive nozzles 11, but under the plate formed by the susceptor holder 6, so that this plate 6 is lifted relative to the support plate 14, without gas being introduced into this intermediate gap space at separate points. The gas that forms the gas bearing exits out of the annular channel substantially in a radial direction both outwardly and also inwardly into the intermediate space between the susceptor holder 6 and the support plate 14.

All disclosed features are (in themselves) pertinent to the invention. The disclosure content of the associated/accompanying priority documents (copy of the prior application) is also hereby incorporated in full into the disclosure of the application, including for the purpose of incorporating features of these documents in claims of the present application.

1. Apparatus for deposition of at least one layer on a substrate, the apparatus comprising one or more susceptors (7) for receiving substrates, a susceptor holder (6) which can be driven in rotation, the susceptor holder defining the floor of a process chamber (2), a heater (22) disposed underneath the susceptor holder (6) and a gas inlet feature (4) for the introduction of process gases into the process chamber, characterized in that the susceptor holder (6) is supported in a floating manner on a support plate (14) which is substantially transparent to IR (infra-red) and/or RF (radio-frequency).

2. Apparatus for deposition of at least one layer on a substrate, the apparatus comprising one or more susceptors (7) for receiving substrates, a susceptor holder (6) which can be driven in rotation, the susceptor holder defining the floor of a process chamber (2), and a gas inlet feature (4) for the introduction of process gases into the process chamber, characterized in that the susceptor holder (6) is supported in a floating manner on a support plate (14), an annular channel (13) being formed in the separation plane between the susceptor holder (6) and the support plate (14), the annular channel being concentric with the axis of rotation of the susceptor holder (6), and gas entry openings (19, 20) associated with the support plate (14) and gas exit openings (28, 11) associated with the susceptor holder (6) opening out into the annular channel.

3. Apparatus according to one or more of the preceding claims or in particular according thereto, characterized in that the susceptor holder (6) is supported on the support plate (14) on a floating gas bearing.

4. Apparatus according to one or more of the preceding claims or in particular according thereto, characterized in that at least one of the one or more susceptors (7) is located in a pocket (10) of the susceptor holder (6) on a rotary gas bearing, the gas for sustaining this rotary gas bearing coming out of an annular channel (13) disposed between the susceptor holder (6) and the support plate (14).

5. Apparatus according to one or more of the preceding claims or in particular according thereto, characterized by the upper wall of the annular channel (13) comprising channels (28) opening out into drive nozzles (11) and connecting with the base (10′) of the pocket (10).

6. Apparatus according to one or more of the preceding claims or in particular according thereto, characterized in that the annular channel (13) is supplied with gas from below through an opening (19) in the support plate (14).

7. Apparatus according to one or more of the preceding claims or in particular according thereto, characterized in that the floating gas bearing between the susceptor holder (6) and the support plate (14) is fed with gas from below by way of through passage openings (19).

8. Apparatus according to one or more of the preceding claims or in particular according thereto, characterized in that the support plate (14) is supported on spherically-shaped flange portions (18) of gas supply lines (15, 16, 17).

9. Apparatus according to one or more of the preceding claims or in particular according thereto, characterized by a rotary drive column (5) which surrounds the center of the process chamber (2) and carries the susceptor holder (6) along in rotation by means of drive features (21).

10. Apparatus according to one or more of the preceding claims or in particular according thereto, characterized by cover plates (8) which lie on the upper side of the susceptor holder (6), this side facing the process chamber (2), and the cover plates defining the circular pockets (10) for receiving the susceptors (7).

11. Apparatus according to one or more of the preceding claims or in particular according thereto, characterized in that the process gases flow through the process chamber (2) in the radial direction.

12. Apparatus according to one or more of the preceding claims or in particular according thereto, characterized by a common gas supply to the gas bearing for support of the susceptor holder (6) on the support plate (14) and for rotational drive of the susceptors (7).
